(19) United States
(12) Patent Application Publication
(10) Pub. No.: US 2006/0028220 A1
(43) Pub. Date: Feb. 9, 2006

(54) Reinforced probes for testing semiconductor devices

(75) Inventors: Edward L. Malantonio, Conshohocken, PA (US); Edward Laurent, North Wales, PA (US); Ilan Hanoon, Glenside, PA (US); Andrew Hmiel, Glenside, PA (US); Bahadir Tunaboylu, Chandler, AZ (US); Anh-Tai Thai Nguyen, Gilbert, AZ (US); Lich Tran, Santa Clara, CA (US)

Correspondence Address: DRINKER BIDDLE & REATH;ATTN: INTELLECTUAL PROPERTY GROUP, ONE LOGAN SQUARE, 18TH AND CHERRY STREETS, PHILADELPHIA, PA, 19103-6996, US

(73) Assignee: K&S Interconnect, Inc.

(21) Appl. No.: 11/184,581

(22) Filed: Jul. 19, 2005

Related U.S. Application Data
(60) Provisional application No. 60/589,618, filed on Jul. 21, 2004.

(51) Int. Cl. G01R 31/02

(52) U.S. Cl. 324/754

(57) ABSTRACT

A probe card assembly is provided. The probe card assembly includes a substrate and a plurality of probes bonded to a surface of the substrate. The probe card assembly also includes a reinforcing layer provided on the surface of the substrate. The reinforcing layer is in contact with a lower portion of each of the probes, where a remaining portion of each of the probes is free from the reinforcing layer.

### RELATED APPLICATIONS

The present application is related to and claims priority from U.S. Provisional Application No. 60/589,618, filed Jul. 21, 2004, which is incorporated herein by reference in its entirety.

### FIELD OF THE INVENTION

The present invention relates to integrity testing of semiconductor devices, and more particularly, to a test probe assembly for testing circuits formed on silicon wafers prior to dicing the wafer into chips.

### BACKGROUND OF THE INVENTION

Integrated circuits typically include a thin chip of silicon, which is formed by dicing a wafer of silicon. Each integrated circuit includes a plurality of input/output pads that are formed on the silicon wafer. In order to assess the operational integrity of the wafer prior to dicing, the silicon wafer is subjected to testing to identify defective circuits.

Known apparatuses for testing silicon wafers include a test controller, which generates integrity test signals, and a probe card, which forms an electrical interface between the test controller and a silicon wafer under test by the apparatus. Known probe cards typically include three major components: (1) an array of test probes; (2) a space transformer; and (3) a printed circuit board (“PCB”). The test probes, which are typically elongate, are arranged for contact with the input/output pads defined by the silicon wafer being tested. The space transformer is respectively connected at opposite sides to the test probes and to the PCB, and converts the relatively high density spacing associated with the array of probes to a relatively low density spacing of electrical connections required by the PCB.

Known test probes include probes that are curved along their length in serpentine fashion to provide for predictable deflection of the probe in response to loads applied to the probe during contact between the probe and a device under test (DUT). In certain probe cards, each of the probes is bonded at one end to a substrate, which may be a contact pad or circuit trace defined on the surface of a space transformer. Loads applied to the probes create stresses in the bonded connection between the probes and the substrate that can lead to failure of the bonded connection.

Thus, it would be desirable to provide a probe card overcoming one or more of the above-recited limitations of conventional probe cards.

### SUMMARY OF THE INVENTION

According to an exemplary embodiment, the present invention relates to a probe assembly for testing integrated circuits. The probe assembly includes a plurality of elongated probes each secured at one end of the probe to a substrate, for example, by bonding the probe to the substrate [e.g., (1) wire bonding a probe to a substrate, (2) pick and place bonding of a probe to a substrate (e.g., using an adhesive, solder, etc.), (3) plating a probe on the substrate through masking techniques, etc.]. The probe assembly also includes a reinforcing layer that is placed onto the substrate such that the connections between the probes and the substrate are covered by the reinforcing layer. Preferably the reinforcing layer is a curable material that is placed onto the substrate while the curable material is in a substantially fluid condition. The hardening of the reinforcing material when it cures results in a strengthened connection between the probes and the substrate.

According to one embodiment of the invention, each of the probes is curved in serpentine fashion and is bonded at one end to a bond pad disposed on a surface of the substrate. The reinforcing layer may be made, for example, from an epoxy resin material and applied to the surface of the substrate such that only a lower portion of the probes adjacent the substrate (e.g., only a few thousandths of an inch of the ends of the probes bonded to the bond pads) are covered by the reinforcing layer.

In certain exemplary embodiments of the present invention, a dam may be used to define a space for containing the reinforcing layer when it is a substantially fluid condition. Preferably, the dam is removable from the probe assembly following hardening of the curable reinforcing layer.

### BRIEF DESCRIPTION OF THE DRAWINGS

For the purpose of illustrating the invention, there is shown in the drawings a form that is presently preferred; it being understood, however, that this invention is not limited to the precise arrangements and instrumentalities shown. In the drawings:

FIG. 1 is a partial side elevation view of a test probe assembly according to an exemplary embodiment of the present invention.

FIG. 2 is an enlarged detail view of an end portion of one of the test probes of FIG. 1.

FIG. 3 is an end elevation view of the test probe assembly of FIG. 1.

FIG. 4a is a top view of a series of bond pads surrounded by a removable dam material in accordance with an exemplary embodiment of the present invention.

FIG. 4b is an end elevation view of the series of bond pads of FIG. 4a including test probes in accordance with an exemplary embodiment of the present invention.

FIG. 5 is an isometric view of an array of probes bonded to a substrate with a reinforcing layer in accordance with an exemplary embodiment of the present invention.

FIG. 6 is a perspective view of a probe showing forces applied thereto in accordance with an exemplary embodiment of the present invention.

FIG. 7 is a flow diagram illustrating a method of processing a probe card assembly in accordance with an exemplary embodiment of the present invention.

### DETAILED DESCRIPTION OF THE DRAWINGS

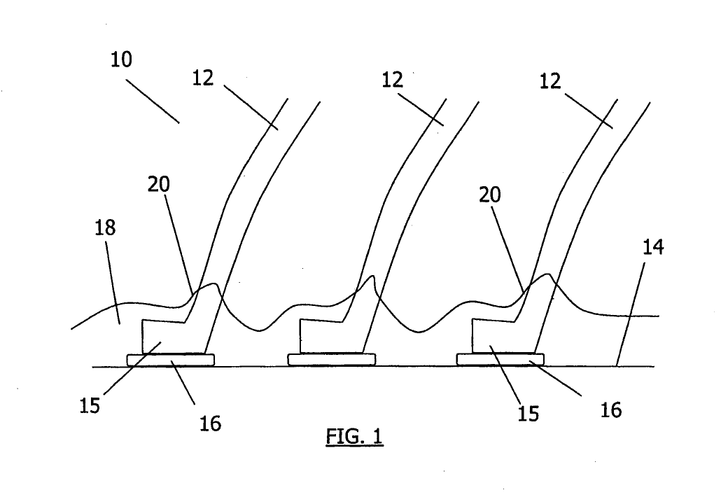

Referring to FIGS. 1 through 3, there is shown a portion of a test probe assembly 10 (e.g., a portion of a probe card assembly) according to the present invention including a plurality of elongated probes 12. The probes 12, which are shown enlarged in the figures to facilitate discussion, may be made from an electroplated material having a thickness of only a few mils. For example, the dimensions of the probes 12 may be approximately 1.0 to 4.0 mils across and approximately 3 mils thick. An exemplary probe size is approximately 2.5 mils by 3.0 mils. The present invention, in the manner described below, provides a reinforced connection between the elongated probes 12 and a substrate 14 (e.g., a space transformer).

The probe assembly 10 of the present invention will preferably form part of a probe card device that is used to test integrated circuits formed on a silicon wafer. When incorporated into a probe card device, the terminal ends of the probes 12 will be brought into contact with bond pads that are formed on the surface of silicon wafer as part of an integrated circuit. The integrated circuit testing via the probe card device will result in the application of force to the elongated probes 12. Testing of ICs on a silicon wafer via bond pads formed on the silicon wafer using testing apparatus incorporating an array of elongated probes is generally known and, therefore, requires no further discussion.

As shown in FIG. 1, each of the elongated probes 12 of the probe assembly 10 is typically curved along its length in serpentine fashion and each of the probes 12 is curved in substantially the same manner as each of the other probes of the probe assembly 10. The bends that are associated with the serpentine curvature of the probes 12 facilitates a spring-like deflection of the probes 12 when the probes 12 are loaded upon contact between the terminal ends of the probes 12 and a testing surface, such as that of a silicon wafer. The similar curvature for each of the probes 12 of the assembly 10 ensures a predictable deflection for a given probe 12 under a given applied load. As a result of the predictable deflection characteristics, the probes 12 are sometimes alternatively referred to as “springs”.

The probes 12 are made, for example, from an electrically conductive metal to facilitate transmission of test signals to bond pads formed on a silicon wafer and to return responsive signals from the silicon wafer to a testing apparatus incorporating the probe assembly 10. For example, the probes may be made from Ni-alloy (s), such as NiMn. Other exemplary materials that may be used include BeCu, Paliney 7, CuNiSi, Molybdenum alloys, Pd alloys, and tungsten alloys. Each of the probes 12 of the assembly 10 is connected to a bond pad 16 through a probe foot 15. The bond pad 16 is formed on the substrate 14 (e.g., a multilayer ceramic or multilayer organic substrate), preferably by bonding the probes 12 in a conventional manner directly to the bond pad 16. Alternately, the probe may be bonded to a separate probe foot and then strengthened as described below. This provides a high bond pad for attaching to the probe. As a result of the bonding, the probe 12 is electrically connected to the bond pads 16 of the substrate 14. Any suitable method of bonding, including well known wire bonding techniques (or pick and place bonding of probes, plating of probes through masking techniques, etc.), could be used to secure the probes 12 of the probe assembly 10 to the bond pads 16 of the substrate 14. It is contemplated that the substrate 14 may not include distinct bond pads 16 but, instead, conductive traces that are formed on the substrate. In such cases each probe end is bonded to a trace. For the purposes of this invention, the term bond pad includes any conductive contact on (or integrated as part of) a substrate.

Depending on the particular application, the substrate 14 may be part of a space transformer for a probe card device. A space transformer converts the close spacing of an array of first contacts (e.g., bond pads) on one side of the space transformer into a less dense spacing of second contacts on an opposite side of the space transformer. The probes 12 provide the electrical connection between the first contacts and the bond pads on a wafer. The second contacts are, during testing, electrically connected to a printed circuit board (e.g., directly or through an interposer) or some other electrical device associated with the testing apparatus.

As described above, the elongated probes 12 of the probe assembly 10 are subjected to applied loads, for predictable spring-like deflection of the probes 12, during contact with a device under test (DUT). To reinforce the connection between the probes 12 of the probe assembly 10 and the substrate 14, a layer 18 of a curable material is placed onto the surface of the substrate 14 such that the bond pads 16 of the substrate 14 are covered. The curable material of the reinforcing layer 18 is then allowed to harden.

The reinforcing layer 18 is preferably made from a non or low conductive material, e.g., has a low dielectric constant, so as to provide very high electrical isolation (insulation) as well as reduced ionics. The reinforcing layer or organics should cause minimal leakage between two signal traces (I/O probes). Preferably the leakage should be less than 10 nA at 3.3 V. According to an exemplary embodiment of the present invention, the conductivity of the reinforcing material is not higher than the conductivity of the substrate 14. As should be apparent from the figures, since the reinforcing layer 18 is contiguous between probes 12, the use of a material that is highly conductive would cause electrical connections between probes, thus potentially creating shorts or incorrect connections. Conductivity through the reinforcing layer 18 may be permissible for common connections (e.g., grounds or power supplies). However, to prevent inadvertent contact with non-common probes and pads, it is preferable that the reinforcing layer 18 is made from non-conductive materials. One preferred materials is a polymer material, such as an epoxy resin material, that is placed onto the underlying surface of the substrate 14 while the polymer material is in a workable, substantially fluid condition. An exemplary material for the reinforcing layer is an epoxy OG198-50 sold by Epoxy Technology, Inc. Other exemplary materials that may be used in the reinforcing layer are alkoxysilane epoxies, acrylate epoxies, tri-functional epoxies, and bi-functional epoxies. The material of the reinforcing layer 18 preferably has a relatively low viscosity prior to hardening to facilitate placement but should possess a medium to high modulus upon curing. The material of the reinforcing layer 18 preferably has adhesive properties sufficient to provide adequate adhesion between the reinforcing layer 18 and both the probes 12 and the substrate 14.

The hardening of the reinforcing layer 18 upon curing of the polymer material results in a relatively rigid formation that strengthens the bonded connection between the probes 12 of the probe assembly 10 and the substrate 14. The reinforcing layer 18 provides strain-relief adjacent the bonded connection that functions to limit bond failures that might otherwise occur during loading and deflection of the probes 12 of the probe assembly 10 during integrity testing of a silicon wafer. The strengthening of the probe connections also tends to increase the amount of force that could be applied to the probes 12 of the probe assembly 10 during a test as compared with a probe assembly having non-reinforced probes. The strengthening of the connection between the probes 12 and the substrate 14 provided by reinforcing layer 18 also allows for reduction in the force that must be applied to the probes 12 during the process of bonding the probes. Such a reduction in the required bonding force functions to limit damage to the bond pads 16 of the substrate 14 that otherwise might occur.

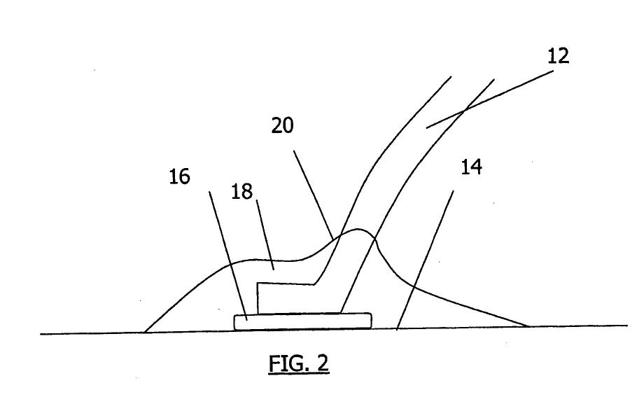

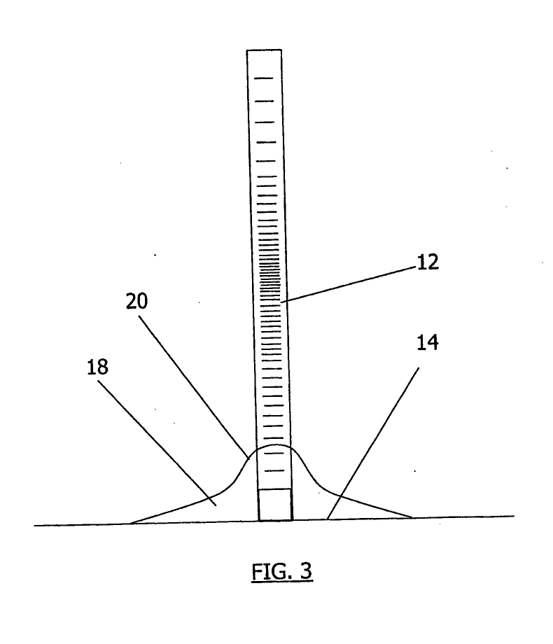

Referring to the enlarged detail view of FIG. 2, the reinforced connection between the substrate 14 and one of the probes 12 of the probe assembly 10 of FIG. 1 is shown in greater detail. As shown, the reinforcing layer 18 is preferably placed onto the surface of substrate 14 in an amount sufficient to cover the bond pads 16 and to define a tapered portion 20 of the polymer material substantially surrounding each of the probes 12 of the probe assembly 10 adjacent the surface of the reinforcing layer 18. The tapered portions 20 of the reinforcing layer 18 are also seen in the end view of the probe assembly shown in FIG. 3. The tapered portions 20 of the reinforcing layer 18 limit stress concentrations that would otherwise be generated in the reinforcing layer 18 adjacent the probes 12 were the surface of the reinforcing layer 18 to be smoothly formed without the tapered portions. The properties of the reinforcing layer are selected to provide the desired adhesion and stress distribution, while also maintaining the height such that the tapered portion 20 does not wick up the length of the probe to such a degree that the flexing function of the probe is diminished. In cases where the wicking may progress to a higher level up the probe 12 due to surface tension and capillary effects, especially when the space between probes becomes small, a self-assembled monolayer (SAM) coating may be applied to a portion of the surface of the probe. The monolayer coating may be a dodecane thiol or other suitable material, such as a alkane thiol. It is generally accepted that self-assembled monolayers preferentially form when the alkane chain is at least 8 carbons in length. See, Loo, et al., “High-Resolution Transfer Printing On GaAs Surfaces Using Alkane Dithiol Monolayers,” J. Vac. Sci. Technol. B, Vol. 20, No. 6, November/December 2002, R. Nuzzo, “The Future Of Electronics Manufacturing Is Revealed In The Fine Print,” Proc. Nat. Acad. of Sciences, Vol. 98, No. 9, Apr. 24, 2001, J. H. Fendler, “Self-Assembled Nanostructured Materials” Chem. Mater: No.8, 1996 and Randy Weinstein et al, “Self-Assembled Monolayer Films from Liquid and Super-Critical Carbon Dioxide”, Ind. Eng. Chem. Res., Vol. 40, 2001. The optional coating uses a hydrophobic surface property that, when applied to the probe above a certain height, will inhibit the tendency of the edge of the tapered portion 20 from rising beyond the coating, and thereby restricting the reinforcing epoxy from the larger share of the probe

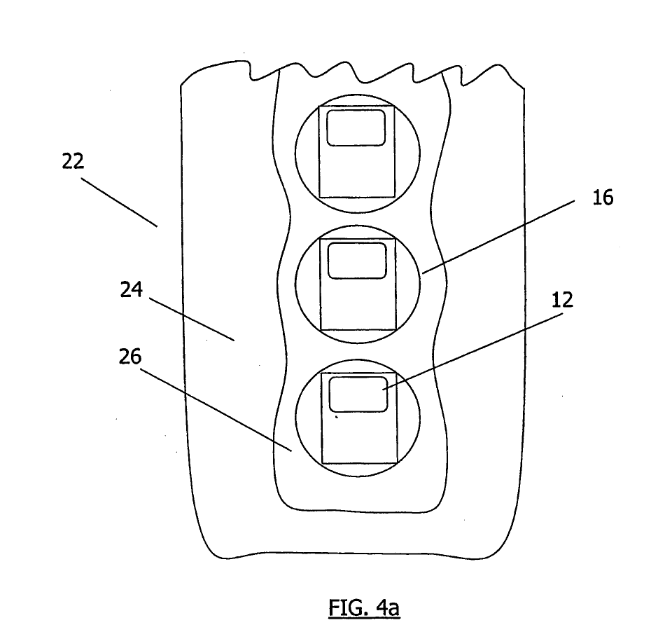

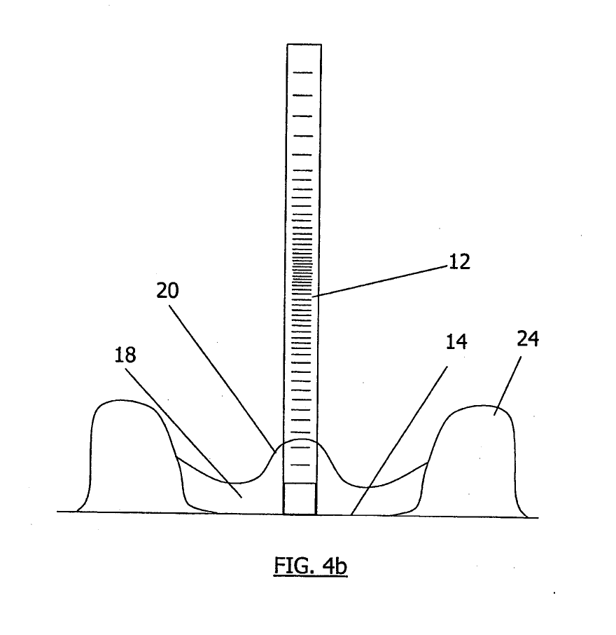

Referring to FIG. 4, there is illustrated a probe assembly 22 according to the invention including a dam 24. The dam 24 functions like a construction form to define a space 26 in which the material of reinforcing layer (not shown) will be placed while in its workable condition, as described above. The dam 24 may be made, for example, from a material such as EdgeControl, sold by Polysciences, Inc. The use of the removable dam 24 provides material saving efficiencies by reducing the size of the reinforcing layer 18 from that which would have to be applied if the material of the reinforcing layer were unconstrained while in was in a fluid condition. Illustrated in FIG. 4b is an end view of the reinforced line of probes 12 with the effect of the presence of the dam 24 on the substrate surface 14 such that the region of the reinforcing layer 18 adjacent to the probe is higher than if the dam 24 were not present or if it were located a much longer distance away from the probes 12. This detail can be seen by comparing FIG. 4b with FIG. 3.

It is also contemplated that removable material could be configured to allow for reworking of the probe assembly 22. In this embodiment, the reinforcing epoxy used should also be removable. The dam may be removed by mechanical means after the assembly is completed. The reinforcing epoxy may also be removed by a suitable solvent whenever a repair of probes is needed. An exemplary reinforcing layer removal process involves the use of a solution of dichloromethane, commonly known as methylene chloride, that may also include a dodecyl benzene sulfonic acid, such as Dynasolve 210 available from Dynaloy, Inc., Indianapolis, Ind., and sonication, followed by an acetone/alcohol rinse and plasma cleaning. According to an exemplary alternative, the coating can be removed by the impact of high velocity CO2 crystals, such as the type available in the use of a “Sno-Gun II” system, from VaTran Systems, Inc.

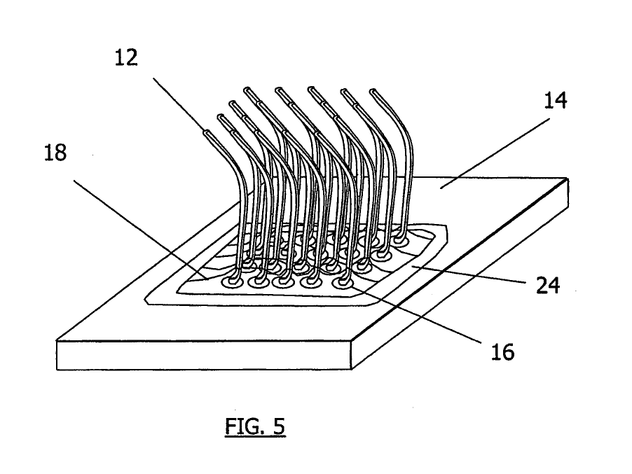

FIG. 5 illustrates a embodiment of the invention where a dam is used for applying the reinforcing layer 18 to an array of probes.

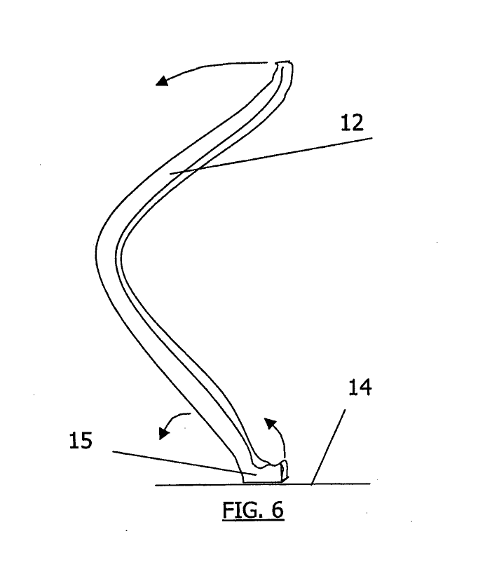

FIG. 6 demonstrates the forces that may be applied during the testing operation of the probes. The application of a scrubbing frictional force at the tip of the probe 12 generally applies a counterclockwise rotation to the probe, as in FIG. 6. This rotation tends to apply a lifting force to the front of the foot 15. The reinforcing function of the epoxy layer is to constrain the front of the foot from lifting. The epoxy is applied to adhere to the sides, rear and top of the foot 15 such that the ability of the reinforcing epoxy to resist the force applied during the probing action. Furthermore, the modulus and the toughness of the epoxy act to maintain its' restraining ability.

The present invention is not limited to any particular method for bonding the probes of the probe assembly to the underlying substrate prior to the placement of the reinforcing layer. The bonding process could incorporate an insulating-type epoxy/encapsulant or a conductive-type adhesive/epoxy applied to the bonded connection following attachment of the probe to the substrate. The bonding process could also incorporate conductive epoxy balls disposed on the substrate before attachment of a probe to provide a no-force attachment of the probe. Alternatively, the bonding process could include a solder ball strengthening of the bonded connection following an ultrasonic attachment of the probe. The bonding process could also include a brazing step.

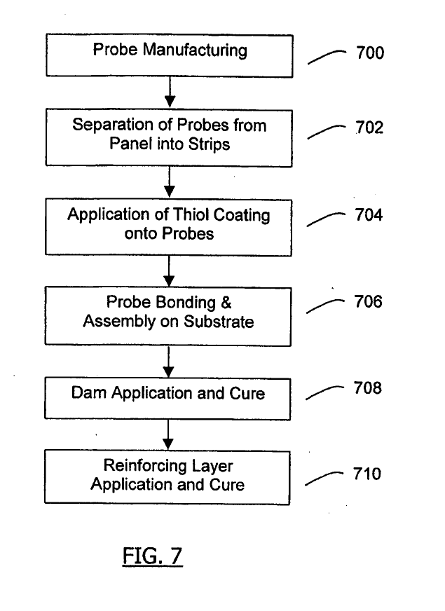

An exemplary method of processing a probe card assembly is illustrated in FIG. 7. As is explained in greater detail below, this exemplary process includes applying (1) a thiol coating, (2) the encapsulant dam and (3) the reinforcing epoxy.

Various steps described below in connection with FIG. 7 are exemplary in nature, and the present invention is not limited to the details illustrated in FIG. 7. For example, certain of the steps may be altered or omitted as desired in accordance with the present invention.

At step 700, a plurality of probes are manufactured (e.g., through a plating process using, for example, photolithography). At step 702, the plurality of probes in a panel form are separated into strips of probes. At step 704, a thiol coating is applied to at least a portion of the length of each of the probes.

For example, the thiol solution used at step 704 may be prepared in anticipation of the processing by mixing a 0.001 molar solution of the particular thiol compound such as hexadecanethiol, in a suitable solvent such as methylene chloride or ethanol. At step 704, the strip of probes is at least partially immersed in the solution (with the thiol container sealed so that evaporative losses of the solvent are limited). After a predetermined period of time (e.g., 2 to 3 hours), the self-assembled films of the thiol solvent are adequately formed and the strip of probes is withdrawn from the solution and rinsed with a thiol-free solvent. The strip air-dries and may then continue in the bonding assembly processes.

More specifically, at step 706, the probes are individually separated from their respective strip and bonded (e.g., wire bonded) to the substrate (e.g., a space transformer).

At step 708, the assembly of probes bonded to the substrate is prepared for the application of the dam and the reinforcing epoxy. More specifically, the dam is applied to the substrate and subsequently cured at step 708. Further, the reinforcing layer is applied to the substrate and subsequently cured at step 710.

For example, in connection with step 708, the dam material may be defrosted from its' storage temperature (e.g., −40° C.) for a predetermined period (e.g., at least one hour) prior to application of the dam to the substrate. The dispensing of the dam may be performed manually or by suitable semi-auto or automatic equipment. The probe assembly can be also fixtured for dispensing using a dispensing controller and a means of X and Y micrometer controlled motion with accurate Z motion of the dispensing syringe, for example, under a microscope. A dispense needle used to form the dam may be, for example, 21 gauge (0.020″ inner diameter) or 20 gauge (0.023″ inner diameter) precision stainless steel style. For example, the dam may be dispensed by bursts (e.g., 1-5 sec) of air pressure (e.g., 25-30 psi) from a dispensing controller. The placement of the dam may be arranged such that any spreading of the dam material will not cover any of the probes, yet, the dam must be applied close enough to the array of probes so that it may function as a support to the level of the reinforcing epoxy. This effect is illustrated in FIG. 4b where the proximity of the dam 24 to the side of the probe 12 maintains a higher level of the reinforcing epoxy 18 than if the dam 24 was not present. If the dam 24 is withdrawn far enough away from the probes 12, the epoxy level support function of the dam 24 will not occur. After completing the placement of the dam 24, the recommended cure procedure is applied. For the case of EdgeControl, an oven cure is recommended (e.g., an oven cure at 110° C. for 60 minutes).

An exemplary embodiment of the present invention employs OG198-50 epoxy which can be stored at room temperature, away from light. The application of the reinforcing epoxy may be performed manually or by suitable semi-auto or automatic equipment. The probe assembly can be also fixtured for dispensing under a microscope on a temperature controlled hotplate and a means of X and Y micrometer controlled motion with accurate Z motion of the syringe. The dispense needle used to apply the epoxy may be, for example, a 32 gauge (0.004″ inner diameter) precision stainless steel style. The epoxy may be dispensed by very short bursts (e.g., 0.05-0.1 sec) of air pressure (e.g., 10-14 psi) from a dispensing controller. The placement of the epoxy is carefully adjusted so that an optimal volume of material is applied to the outer areas of the pattern of the probes and carefully monitored to observe the progress of the epoxy as it flows in between the probes in the array. The height of the reinforcing epoxy is controlled by the precise application of sufficient epoxy in areas that have a shortage of the material. It may also be advantageous to use a slight vacuum on an alternate tool to withdraw epoxy from places where an abundance of the material exists.

After the array is viewed from various angles to ascertain the correct level of epoxy has been applied and that all probes are sufficiently covered, the recommended cure for the material is applied. In an exemplary embodiment, using OG198-50, the assembly is placed on a flat carrier in an oven (e.g., at 110° C.) and the oven follows a cure schedule (e.g., a schedule of a ramp from 110° C. to 150° C. in 8 minutes and dwells at 150° C. for one hour). The end of the cure cycle then ramps down to room temperature.

Exemplary processes for removal of the reinforcing material may be dependent on the characteristics of the substrate materials. For example, on ceramic substrates with gold over nickel over copper vias, immersion in a warm solution of methylene chloride followed by a furnace bake for 20 minutes at 525° C. is effective for removing the epoxy. The pads may then be cleaned of the residual carbon that is typically left on them. The use of the impact of high velocity CO2 crystals, such as the type available in the use of a “Sno-Gun II” system, is effective at removing the carbon so that the substrate can be re-bonded. For other types of substrates more exotic means of removing the epoxy, for example, using custom solvents, high intensity UV exposure or the impact of high velocity CO2 crystals, from the “Sno-Gun II” system may provide desirable results.

Although the present invention has been illustrated in connection with relatively small numbers of probes, it is clear that the invention has application where many (e.g., thousands and more) probes are mounted to a substrate, for example, in connection with a probe card assembly.

The foregoing describes the invention in terms of embodiments foreseen by the inventor for which an enabling description was available, notwithstanding that insubstantial modifications of the invention, not presently foreseen, may nonetheless represent equivalents thereto.

What is claimed is:

1. A probe card assembly comprising:
a substrate;
a plurality of probes bonded to a surface of the substrate; and
a reinforcing layer provided on the surface of the substrate, the reinforcing layer being in contact with a lower portion of each of the probes, a remaining portion of each of the probes being free from the reinforcing layer.

2. The probe card assembly of claim 1 wherein the substrate is a space transformer.

3. The probe card assembly of claim 1 wherein the reinforcing layer is an insulative material.

4. The probe card assembly of claim 1 wherein the reinforcing layer comprises an epoxy material.

5. The probe card assembly of claim 1 wherein the reinforcing layer includes tapered portions adjacent the probes, the tapered portions being thicker than a remainder of the reinforcing layer.

6. The probe card assembly of claim 1 wherein the probes include a coating to reduce a potential for the reinforcing layer to extend up the probes beyond the lower portion.

7. The probe card assembly of claim 1 further comprising a dam structure for defining a region of the substrate where the reinforcing layer is disposed.

8. A method of processing a substrate comprising the steps of:
bonding a plurality of probes to a surface of the substrate; and
dispensing a reinforcing layer on the surface such that the reinforcing layer covers only a lower portion of each of the probes.

9. The method of claim 8 further comprising the step of:
curing the reinforcing layer after the dispensing step.

10. The method of claim 8 wherein the bonding step includes at least one of (1) wire bonding the probes to the surface of the substrate, (2) pick and place bonding the probes to the surface of the substrate, or (3) plating the probes on the substrate using masking techniques.

11. The method of claim 8 wherein the dispensing step includes dispensing the reinforcing layer in a flowable state on the surface of the substrate.

12. The method of claim 8 further comprising the step of:
providing a dam structure on the surface of the substrate prior to the dispensing step, the dam structure defining a region of the substrate where the reinforcing layer is to be disposed.

13. The method of claim 12 wherein the providing step includes dispensing a dam structure material on the surface of the substrate and curing the dam structure material to provide the dam structure.

14. The method of claim 13 wherein the dispensing step includes dispensing the reinforcing layer within the region defined by the dam structure.

15. The method of claim 8 further comprising the step of:
applying a coating to at least a portion of each of the probes prior to the dispensing step such that a potential for the reinforcing layer to extend up the probes beyond the lower portion is reduced.

16. The method of claim 8 wherein the dispensing step includes dispensing the reinforcing layer such that the reinforcing layer includes tapered portions adjacent the probes, the tapered portions being thicker than a remainder of the reinforcing layer.

17. The method of claim 8 further comprising the steps of:
removing at least a portion of the reinforcing layer; and
applying another reinforcing layer to the surface of the substrate.

18. The method of claim 17 wherein the step of removing includes immersion of at least a portion of the substrate into a solution, the solution facilitating removal of the portion of the reinforcing layer.
